(19) United States
(12) Patent Application Publication
(10) Pub. No.: US 2013/0136277 A1
(43) Pub. Date: May 30, 2013

(54) VOLUME CONTROLLER, VOLUME CONTROL METHOD AND ELECTRONIC DEVICE

(71) Applicant: Takashi Sudo, Fuchu-shi (JP)

(72) Inventor: Takashi Sudo, Fuchu-shi (JP)

(73) Assignee: KABUSHIKI KAISHA TOSHIBA, Tokyo (JP)

(21) Appl. No.: 13/608,873

(22) Filed: Sep. 10, 2012

(30) Foreign Application Priority Data
Nov. 28, 2011 (JP) 2011-259633

(51) Int. Cl. H03G 3/20

(52) U.S. Cl. 381/107

(57) ABSTRACT

According to at least one embodiment, a volume controller includes an audio processor configured to generate an output signal by variably controlling an amplitude of an input signal; and a volume controller configured to set a sound volume for the variable control based on the input signal.

### CROSS-REFERENCE TO RELATED APPLICATION(S)

The application is based upon and claims the benefit of priority from Japanese Patent Application No. 2011-259633 filed on Nov. 28, 2011, the entire contents of which are incorporated herein by reference.

### FIELD

Embodiments described herein relate generally to a volume controller, a volume control method and an electronic device.

### BACKGROUND

There have been proposed a variety of sound volume control techniques. For example, there is proposed a volume control method in which a short time average amplitude of an input signal is used to calculate gain with a Normalized Least Mean Squares (NLMS) algorithm to produce a least square error between the short time average amplitude of the input signal and a target amplitude, so that sound volume of the signal can be made uniform. However, since the target amplitude is fixed and amplitudes of all signals become uniform to approach the target amplitude, a frequency characteristic is changed to degrade quality of the signal that is problematic.

In addition, there has been known a technique called “dynamic range control” to output an amplitude depending on an amplitude of an input signal according to a nonlinear curved line function. However, this technique processes the amplitude of the input signal for every sample or in a short period of time, and thus, the total sound volume of contents cannot be controlled which is problematic as well.

Although there is a need for a technique to make a sound volume uniform with a little process delay and small amount of processing by, for example, nonlinearly controlling the volume in a short time, means for realizing such a need has not yet been known in the related art.

### BRIEF DESCRIPTION OF DRAWINGS

A general architecture that implements the various features of the present invention will now be described with reference to the drawings. The drawings and the associated descriptions are provided to illustrate embodiments and not to limit the scope of the present invention.

FIG. 1 is a schematic view illustrating an appearance of an electronic device according to an exemplary embodiment of the present invention.

FIG. 2 is a block diagram illustrating an exemplary hardware configuration of the electronic device according to the exemplary embodiment.

FIG. 3 is a functional block diagram of an audio reproduction function of the exemplary embodiment (Example 1).

FIG. 4 is a functional block diagram of a voice collection function of the exemplary embodiment.

FIG. 5 is a functional block diagram of a main function in the exemplary embodiment (Example 1).

FIG. 6 is a flow chart showing the operation of main parts in the exemplary embodiment (Example 1).

FIG. 7 is an explanatory view of a target amplitude determination unit 2C in the exemplary embodiment.

FIG. 8 is an explanatory view of a target amplitude determination unit 2C in the exemplary embodiment (in accordance with a user volume).

### DETAILED DESCRIPTION

Embodiments of the present invention has been made in an effort to provide a technique for making a volume of sound uniform with a small amount of processing.

Hereinafter, the embodiments of an electronic device and a control method thereof will be described in detail with reference to the accompanying drawings.

The following embodiments will be illustrated with a hand-held electronic device such as a personal digital assistant (PDA), a mobile phone or the like.

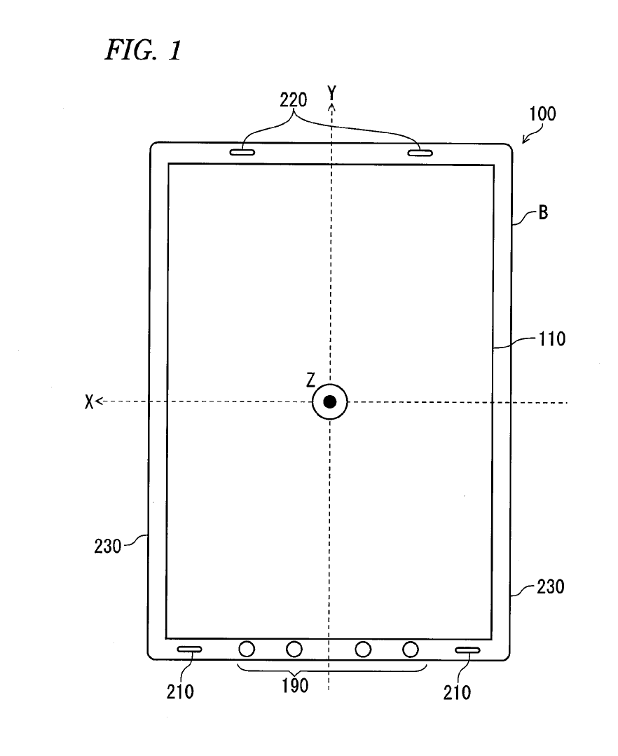

FIG. 1 is a schematic view illustrating an appearance of an electronic device 100 according to an exemplary embodiment of the present invention. The electronic device 100 is implemented with an information processing device equipped with a display screen, such as a slate terminal (or a tablet terminal), an electronic book reader, a digital photo frame or the like. In this figure, the direction of the arrows in the X, Y and Z axes (the front direction of the figure for the Z axis) are assumed to be plus (+) directions (the same notational convention is used hereinafter).

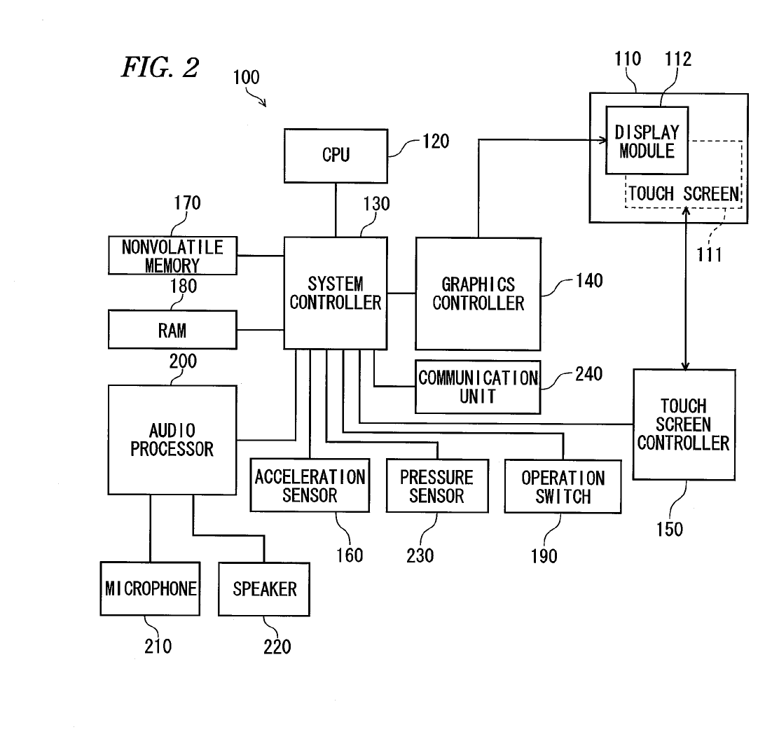

The electronic device 100 has a thin box-like case B on which a display module 110 is disposed. The display module 110 includes a touchscreen (see, for example, a touchscreen 111 in FIG. 2) that detects a position on a display screen touched by a user. On the front lower part of the case B are disposed operation switches 190 for various operations by the user, and microphones 210 for acquisition of user's voice. On the front upper part of the case B are disposed speakers 220 for audio output. Pressure sensors 230 for detection of user's holding are disposed on edges of the case B. Although it is shown in the figure that the pressure sensors 230 are disposed on left and right edges in the X-axis direction, the pressure sensors 230 may be disposed on top and bottom edges in the Y-axis direction.

FIG. 2 is a block diagram illustrating an exemplary hardware configuration of the electronic device 100. As shown in FIG. 2, in addition to the above configuration, the electronic device 100 includes a central processing unit (CPU) 120, a system controller 130, a graphics controller 140, a touchscreen controller 150, an acceleration sensor 160, a nonvolatile memory 170, a random access memory (RAM) 180, audio processor 200, a communication module 240 and so on. The audio processor 200 is connected to the internal or external microphones 210 and speakers 220.

The display module 110 includes a touchscreen 111 and a display module 112 such as a liquid crystal display (LCD) module or an organic electroluminescent (EL) display module. The touchscreen 111 is configured by a coordinate detector disposed on the display screen of the display module 112. The touchscreen 111 can detect a (touch) position on the display screen touched by a user's finger that holds the case B firmly. With the operation of the touchscreen 111, the display screen of the display module 112 acts as a so-called touch screen.

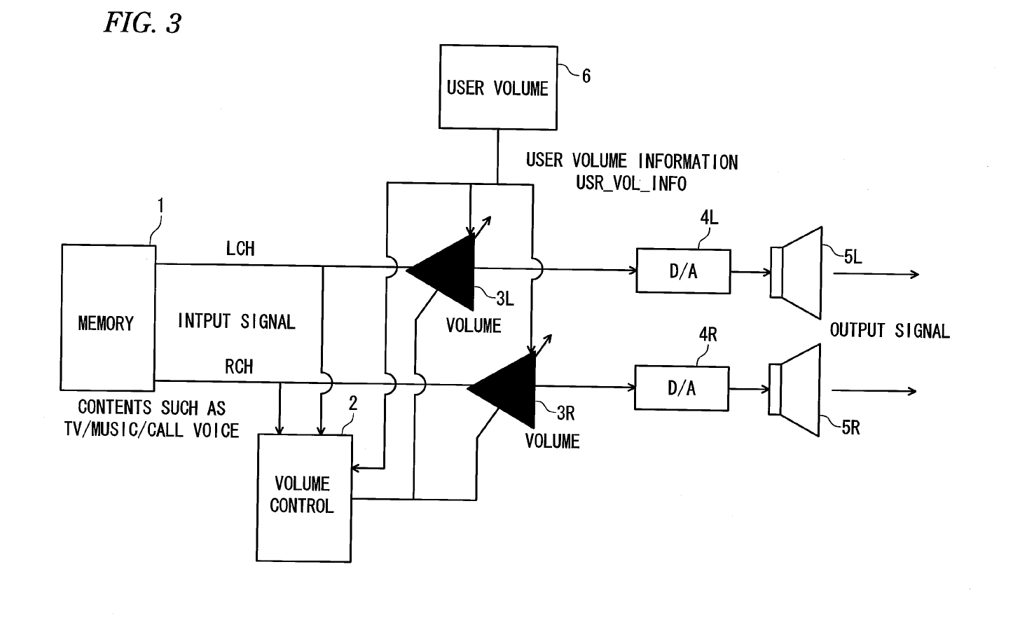

The CPU 120 is a processor that controls the operation of the electronic device 100, and thus, each component of the electronic device 100 is controlled through the system controller 130. The CPU 120 executes an operating system and various application programs loaded from the nonvolatile memory 170 into the RAM 180 to implement various functional units (see, for example, FIG. 3) that will be described later. The RAM 180 is a main memory of the electronic device 100 and provides a work area to be used when the CPU 120 executes the programs.

The system controller 130 incorporates a memory controller that controls access to the nonvolatile memory 170 and the RAM 180. The system controller 130 also has a function to conduct communication with the graphics controller 140. The system controller 130 also has a function of transmitting an audio signal such as a voice waveform to an external server (not shown) via the Internet or the like via communication module 240 and receiving a result of voice recognition for the voice waveform as necessary, or a function of transmitting music information selected by a user to an external server (not shown) and receiving a reproduced sound of the music as necessary via communication module 240.

The graphics controller 140 is a display controller that controls the display module 112 used as a display monitor of the electronic device 100. The touchscreen controller 150 controls the touchscreen 111 and acquires from the touchscreen 111 coordinate data representing a touch position on the display screen of the display module 112 touched by the user.

The acceleration sensor 160 is, for example, a 6-axial acceleration sensor configured to detect acceleration in three axial directions (X, Y and Z-axis directions) and rotational directions around the axes. The acceleration sensor 160 detects the direction and magnitude of acceleration from the outside with respect to the electronic device 100, and outputs the detected direction and magnitude of acceleration to the CPU 120. Specifically, the acceleration sensor 160 outputs an acceleration detection signal (gradient information) including an acceleration-detected axis, direction (rotation angle in case of rotation) and size of the acceleration to the CPU 120. A compass sensor capable of detecting angular velocity (rotation angle) may be incorporated in the acceleration sensor 160.

The audio processor 200 is operated upon executing an audio function and a voice function. First, the audio function will be described. An example of the audio function may include audio playback. Under the control of the CPU 120, the audio processor 200 performs an audio processing on a music waveform of audio contents stored in the nonvolatile memory 170 using an equalizer or the like to produce an audio signal and outputs the produced audio signal to the speaker 220 by which the audio signal is reproduced (e.g., played back). Next, the voice function will be described. Examples of the voice function may include voice recording, voice reproduction, voice call and voice notification. The audio processor 200 performs a speech processing such as digital conversion, noise cancellation, echo cancellation and so on for a voice signal input from the microphone 210 and outputs the processed voice signal to the CPU 120 for voice recording. In addition, under the control of the CPU 120, the audio processor 200 performs a speech signal processing on a voice signal by using an equalizer or the like to produce a voice signal and outputs the produced voice signal to the speaker 220 by which voice is reproduced. For a voice call such as Voice over Internet Protocol (VoIP), the above-mentioned voice recording and voice reproduction are simultaneously processed. Further, under the control of the CPU 120, the audio processor 200 may perform a speech signal processing such as speech synthesis or the like on a voice signal and output the produced voice signal to the speaker 220 so that a voice notification function may be realized. More details of the audio processor 200 will be described later.

FIG. 3 is a functional block diagram of an audio reproduction function according to the exemplary embodiment. The audio reproduction function shown in the figure is realized based on the functions of a memory 1 corresponding to the RAM 180 through speakers 5 (left speaker 5L and right speaker 5R) corresponding to the speaker 220 of the audio processor 200. As shown in the figure, a user volume (volume switch) 6 is connected to a volume controller 2, volumes 3 (left volume 3L and right volume 3R) and D/A converters 4 (left D/A converter 4L and right D/A converter 4R).

Audio contents such as TV programs, music, Internet moving picture contents and so on stored in the memory 1 corresponding to the nonvolatile memory 170 are reproduced via the system controller 130. The audio contents are decomposed to an input signal x[n] (n=0, 1, 2, . . . ) and becomes an L/R stereo signal with 48 kHz sampling rate. The volume controller 2 analyzes the input signal x[n] to calculate a volume (gain), sets the calculated sound volume (gain) to the volume 3, and calculates an output signal y[n] by multiplying the input signal x[n] with the calculated gain. The calculated output signal y[n] is outputted through the D/A converters 4 and the speakers 5. A user volume (a target amplitude of which is varied depending on a digital user volume) set by a user operating the user volume 6 is input to the volume controller 2 as user volume information. As for the user volume 6, the user volume information may be interactively input from the touchscreen 111 corresponding to, for example, a volume-shaped GUI displayed on the display module 112.

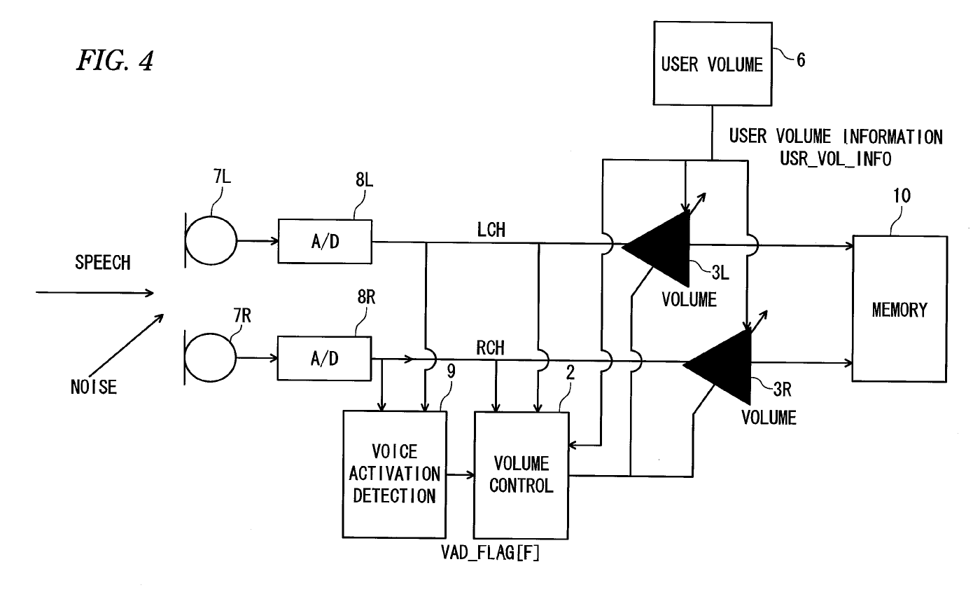

As another example, there is a usage of voice recording that collects audio signals. FIG. 4 is a functional block diagram of voice recording. Voice and noise input from microphones 7 (left microphone 7L and right microphone 7R) are A/D-converted by A/D converters (left A/D converter 8L and right A/D converter 8R) and then introduced into a voice activity detector 9. If a target object whose volume of the sound is controlled by the volume controller 2 is human voice, the voice activity detector 9 detects, in advance, voice activity, which is information indicating whether or not the human voice is present, and inputs flag (VAD_FLAG[f]) of the voice activity to the volume controller 3.

As still another example, there is a usage of voice reproduction that reproduces voice signals. In this case, although the voice signals are reproduced from the speakers 5 via the volume controller 2 and the volume 3, similarly as in the above-described usage of audio reproduction, since an input signal controlling a sound volume with the volume controller 2 is a human voice, the voice activity detector 9 detects, in advance, voice activity, which is information indicating whether or not the human voice is present, and inputs flag (VAD_FLAG[f]) of the voice activity to the volume controller 3.

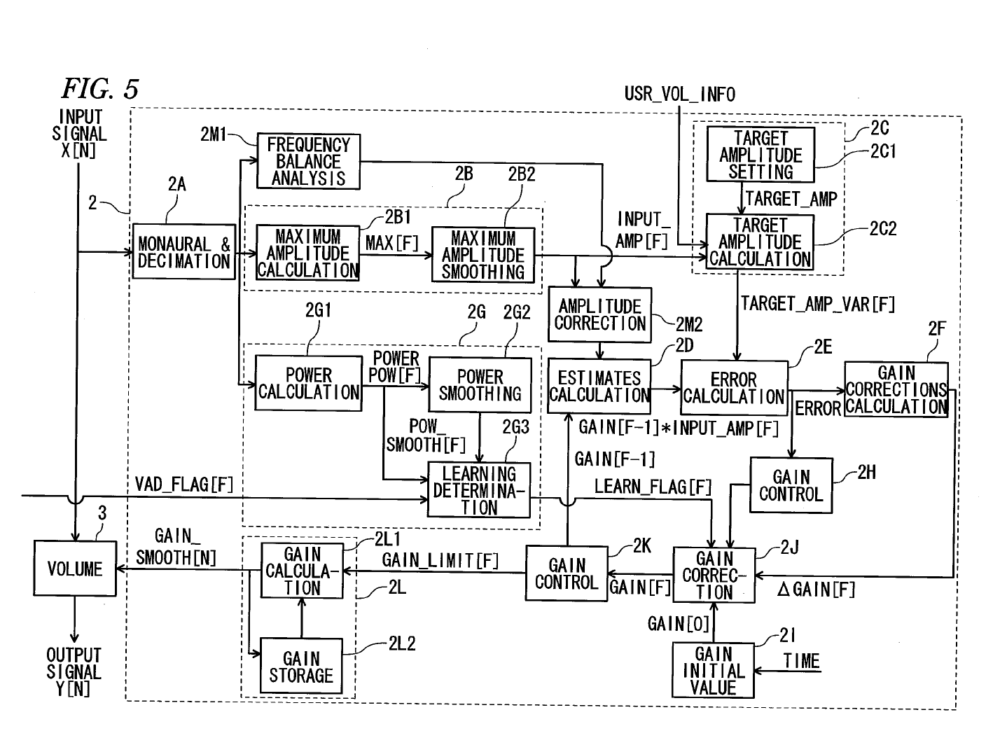

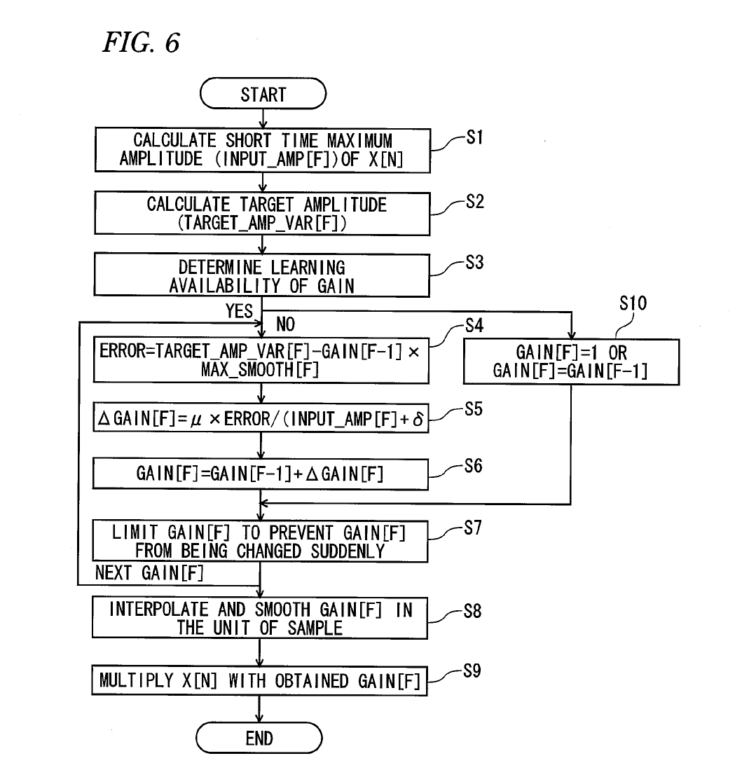

FIG. 5 is a block diagram of the volume controller 2 and the operation of the volume controller 2 will be described below with reference to FIG. 5 in conjunction with a flow chart shown in FIG. 6.

First, an input signal x[n] of an L/R stereo signal with 48 kHz sampling rate is converted (2A) to a monaural signal with 16 kHz sampling rate fin order to reduce an amount of processing. The maximum amplitude (max[f] [dB]) of an absolute value of the monaural signal reached in a short time interval (for example 5 [ms], hereinafter referred to as a “frame”) is calculated (2B, 2B1). Regarding the maximum amplitude to be reached in the short time interval, the monaural signal may be smoothed to output max_smooth[f] [dB] (2B2) by constructing an omniploar filter by which past values of the monaural signal are ignored. Accordingly, max_smooth[f] in dB is converted to a basis in amplitude value and output as input_amp[f] (step S1 in FIG. 6). By using the maximum value instead of the mean value, the quality of a signal after being subjected to a volume of the sound control processing can be prevented from being deteriorated due to the clipping of the signal. For example, an impulse signal may be used to prevent the quality of signal from being deteriorated.

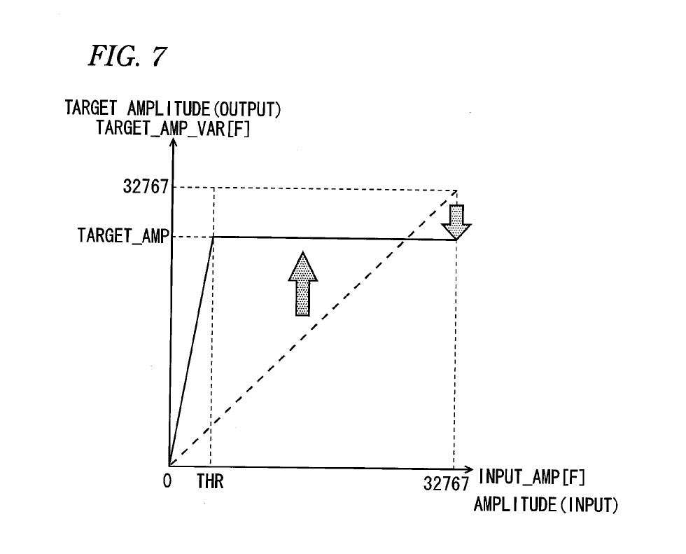

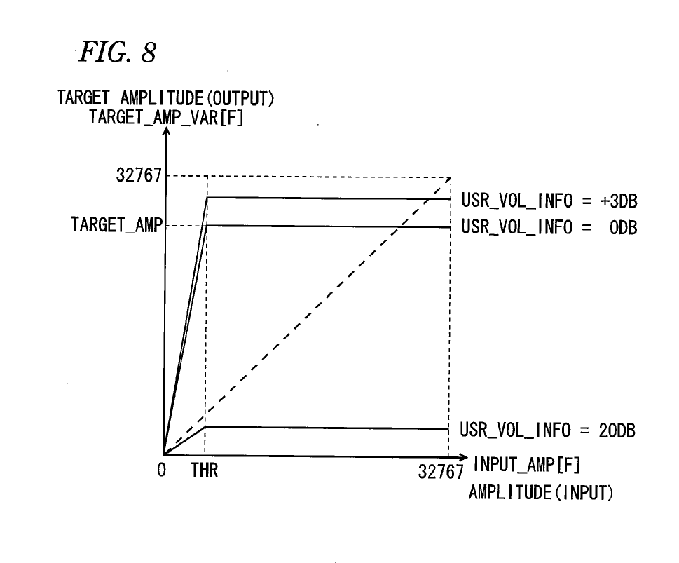

A target amplitude determination unit 2C includes a target amplitude setting part 2C1 and a target amplitude calculation part 2C2. For example, the target amplitude setting part 2C1 maintains a relationship between an input amplitude (input_amp[f]) and a target amplitude (target_amp_var[f]) by preset threshold values (for example, TARGET AMP, THR, etc.), as shown in FIG. 7. The target amplitude calculation part 2C2 determines each of different target amplitudes (target_amp_var[f]) for different frames from each of different input amplitude (input_amp[f]) for different frames (step S2 in FIG. 6). In addition, the target amplitude calculation part 2C2 may determine the target amplitude based on user volume information (usr vol_info) obtained from the user volume 6, as shown in FIG. 8. Thus, a user volume to amplify/attenuate a digital signal may be together used. The signal may be clipped if the user volume is positioned at the rear of the volume controller 2. In the mean time, if the user volume is positioned in front of the volume controller 2, the sound volume of the signal becomes uniformalized and a user is prevented from changing the volume.

A learning availability determination unit 2G includes a power calculation part 2G1 that calculates short time power (pow[f]) of the input signal x[n], a power smoothing part 2G2 that smoothes the short time power, and a learning determination part 2G3 that outputs a flag (learn_flag[f]) indicating that a gain correction operation (that will be described later) is to be performed, only when the smoothed power (powsmooth[f]) exceeds a preset threshold value. Alternatively, if an object whose volume of the sound is controlled by the volume controller 2 is a human voice, the learning determination part 2G3 obtains an output (VAD_FLAG[f]) from the voice activity detector 9 and outputs the flag (learn_flag[f]) indicating that the gain correction operation (that will be described later) only when an interval during which it is determined that the input signal x[n] is human voice and the smoothed power (pow_smooth[f]) exceeds a preset threshold value (step S3 in FIG. 6).

When it is determined that the gain correction operation is to be performed, the following process is performed. An estimate calculation unit 2D uses a gain (Gain[f−1]) in the immediately previous frame to calculate a magnitude of the input signal x[n] as input_amp [f]×Gain[f−1].

In more detail, although the sound volume may be in auditory unbalance if there are many low frequency domains, in order to reduce an amount of processing, frequency balance analysis (2M1) and amplitude correction (2M2) are sequentially performed, and a result of the amplitude correction is used at the estimate calculation unit 2D.

1) A first-order or second-order IIR filter is used to calculate power in a low frequency domain.

2) Since the less the number of zero-crosses, the more the low frequency components, and auditory sound volume felt by the human becomes higher than computational volume (amplitude), the amplitude is corrected to be larger.

Next, an error calculation unit 2E obtains an error between the corrected amplitude and a target amplitude, as target_amp_var[f]-input_amp[f]×Gain[f−1] (step S4 in FIG. 6). A gain correction calculation unit 2F calculates a gain correction Δ(delta)gain[f]=μ×error/(input_amp[f]+δ) according to the NLMS algorithm, which is one of learning identification methods, to provide a least square error with the target amplitude (step S5 in FIG. 6). A gain correction unit 2J calculates a new gain as Gain[f]=Gain[f−1]+Δgain[f] (step S6 in FIG. 6). Where, μ represents a step size (or step gain) and δ is an integer to prevent a denominator from being 0.

On the one hand, if it is determined that the gain correction operation is not to be performed, the gain is set such that Gain[f]=1 (gain value remains 1 when not learning if the overall gain is intended to be large) or Gain[f]=Gain[f−1] (gain value remains the immediately previous gain value if the gain is intended to be small) (step S10 in FIG. 6), and then, the process proceeds to step S7.

As a gain initial value 21, Gain[0]=1 is stored and used. This can prevent the initial gain from being huge. A gain controller 2H decreases Δgain[f] so that the gain is unchanged if an absolute value of error is larger than a predetermined threshold value. In addition, if error is larger than input_amp[f], Δgain[f] is decreased so that the gain is unchanged. This can prevent the gain from being increased and clipped accidentally. A gain controller 2K limits Δgain[f] so that Δgain[f] is prevented from being amplified to more than 3 [dB] or attenuated to more than −0.25 [dB] (step S7 in FIG. 6). Step S4 and the following steps are repeated until a frame being a target object for obtaining Gain[f] is not present.

Since the obtained Gain[f] has the unit of frame, a gain smoothing unit 2L calculates a gain (Gain_smooth[n]) in the unit of sample by linearly interpolating the obtained Gain[f] using Gain[f−1] (step S8 in FIG. 6).

Finally, a volume 3 calculates an output signal y[n] by multiplying the input signal x[n] with the gain (Gain_smooth[n]) (step S9 in FIG. 6). The controller 2 calculates a monaural gain and multiplies an L/R channel with the same gain such that a stereo effect is unchanged.

Advantages of the above embodiment are as follows.

(1) The multiplication of the input signal with the calculated gain can prevent the input signal from being clipped. The input signal is hardly clipped even when an accidental signal such as an impulse is input.

(2) The total sound volume of contents can be controlled with a little change in sound quality.

(3) The total sound volume of contents can be controlled in association with the user volume.

According to the above-described embodiment, a process having the following characteristics can be performed.

(1) Setting the target amplitude (2C2) by using the maximum amplitude of the input signal reached in the short time interval is used (2B).

(2) Changing the target amplitude (TARGET AMP) in association with the digital user volume (usr vol_info) (2C2).

(3) Calculating a Gain (2D, 2F, 2J, 2K) according to the NLMS algorithm by using the maximum amplitude of the input signal reached in the short time interval (2B) such that the least square error (2B) between the short time average amplitude of the input signal and the target amplitude (target_amp_var) is provided.

(4) Limiting (non-linearity, gradient, etc.) the gain so that change is smaller (2H) when an absolute value of an error between the short time average amplitude of the input signal and the target amplitude is large.

(5) Calculating the gain in increments of short time (2K) and linearly complementing in increments of sample (2L), and multiplying the input signal by the complemented gain (3).

The present embodiment provides a sound volume control method capable of making a volume of an input signal to be uniform by using the maximum amplitude of the input signal reached in the short time interval to set a target amplitude according to a nonlinear curved line function and calculate a gain according to the NLMS algorithm to provide the least square error between the short time average amplitude of the input signal and the target amplitude.

The conventional methods using an average amplitude are likely to produce a relatively large gain. In contrast, the present embodiment can prevent the input signal from being clipped by multiplying the input signal with the gain calculated using the maximum amplitude reached in the short time interval.

The present embodiment can control the total sound volume of contents with little change in sound quality by dynamically changing the target amplitude such that a small input provides a small output whereas a large input provides a large output.

The above embodiments are not intended to be limited but may be modified and practiced in various ways without departing from the spirit and scope of the present invention.

The invention is not limited to the aforementioned embodiments and components may be modified to embody the invention without departing from the sprit thereof. Components of the embodiments may be suitably and variously combined. For example, some of all components of each embodiment may be omitted, and components of different embodiments may be combined suitably.

What is claimed is:

1. A volume controller comprising:
an audio processor configured to generate an output signal by variably controlling an amplitude of an input signal in accordance with an audio volume; and
a volume controller configured to control the audio processor to set the audio volume based on the input signal.

2. The volume controller of claim 1 further comprising:
a user volume configured to allow an user to input a target amplitude,
wherein the volume controller sets or changes the target amplitude in accordance with the user volume.

3. The volume controller of claim 1,
wherein the volume controller sets a sound volume according to a learning identification method such that an error between a maximum amplitude of the input signal reached in a short time interval and the target amplitude is reduced.

4. The volume controller of claim 1,
wherein the volume controller imposes a limitation such that change in the volume setting is decreased when an absolute value of the error is large.

5. An electronic device comprising:
an audio processor configured to generate an output signal by variably controlling an amplitude of an input signal in accordance with an audio volume;
a volume controller configured to control the audio processor to set the audio volume based on the input signal; and
an output unit configured to generate a sound based on the output signal.

6. An audio control method comprising:
setting an audio volume for a variable control of an amplitude from an input signal; and
generating an output signal by variably controlling the input signal.
